(19) United States
(12) Patent Application Publication
(10) Pub. No.: US 2015/0249448 A1
(43) Pub. Date: Sep. 3, 2015

(54) Electronic Circuit Operable as an Electronic Switch

(71) Applicant: Infineon Technologies Austria AG, Villach (AT)

(72) Inventors: Franz Hirler, Isen (DE); Joachim Weyers, Hoehenkirchen (DE); Anton Mauder, Kolbermoor (DE)

(21) Appl. No.: 14/193,517

(22) Filed: Feb. 28, 2014

(51) Int. Cl. H03K 17/567; H03K 17/687

(52) U.S. Cl. CPC H03K 17/567; H03K 17/687

(57) ABSTRACT

An electronic circuit includes an input node configured to receive an input voltage, and a load path between a first load node and a second load node. The circuit further includes a first transistor device, and n second transistor devices, with n≧1, wherein load paths of the first transistor device and the n second transistor devices are connected in series, thereby forming the load path of the electronic circuit. Each of the first transistor device and the n second transistor devices has a drive node coupled to the input node of the electronic circuit. Each of the n second transistor devices has the drive node coupled to the load path of the electronic circuit.

### TECHNICAL FIELD

This disclosure in general relates to an electronic circuit and, more specifically, relates to an electronic circuit that can be operated as an electronic switch.

### BACKGROUND

Electronic switches are widely used in different types of electronic circuits in automotive, industrial, consumer electronics or household applications. Conventionally, power transistors, such as power MOSFETs (Metal Oxide Field-Effect Transistors) or power IGBTs (Insulated Gate Bipolar Transistors) are used as electronic switches. Those power transistors are available with different voltage blocking capabilities, such as voltage blocking capabilities between several 10V and several 100V. The voltage blocking capability is dependent on the specific design of the power transistor. That is, for each voltage blocking capability, a specific design and a dedicated manufacturing process is required. Further, the on-resistance (which is the electrical resistance of the power transistor in the on-state) increases as the voltage blocking capability increases.

### SUMMARY

One embodiment relates to an electronic circuit. The electronic circuit includes an input node configured to receive an input voltage, and a load path between a first load node and a second load node. The electronic circuit further includes a first transistor device and n second transistor devices, with n≧1. The load paths of the first transistor device and the n second transistor devices are connected in series, thereby forming the load path of the electronic device. Each of the first transistor device and the n second transistor devices has a drive node coupled to the input node of the electronic circuit, and each of the n second transistor devices has the drive node coupled to the load path of the electronic circuit.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 illustrates one embodiment of an electronic circuit that includes a first transistor device and n (with n=4) second transistor devices.

FIGS. 2a-2b show two different embodiments of a voltage limiting element in the electronic circuit shown in FIG. 1.

FIG. 3 illustrates an embodiment of an electronic circuit that includes a first transistor device 1 and only one (n=1) second transistor device.

FIG. 4 illustrates a modification of the electronic circuit shown in FIG. 1.

FIG. 5 illustrates another embodiment of an electronic circuit that includes a first transistor device and n second transistor devices.

FIG. 6 illustrates an embodiment of an electronic circuit that includes a first transistor device, n second transistor devices and further voltage limiting elements connected in parallel with load paths of the first transistor device and the second transistor devices.

FIG. 7shows one embodiment of a voltage limiting element that includes at least one Zener diode.

FIG. 8 shows one embodiment of a voltage limiting element that includes at least one transistor.

### DETAILED DESCRIPTION

In the following detailed description, reference is made to the accompanying drawings. The drawings form a part of the description and by way of illustration show specific embodiments in which the invention may be practiced. It is to be understood that the features of the various embodiments described herein may be combined with each other, unless specifically noted otherwise.

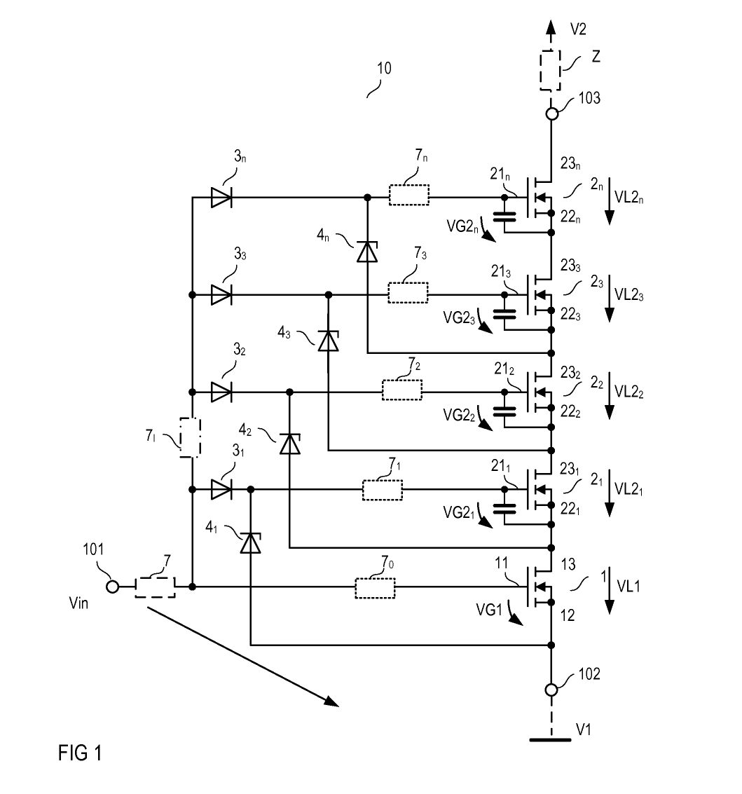

FIG. 1 shows one embodiment of an electronic circuit 10 that can be used as an electronic switch. The electronic circuit 10 includes a drive node 101 configured to receive an input voltage Vin, and a load path between a first load node 102 and a second load node 103. A first transistor device 1 and at least one second transistor device 2₁-2ₙ have their load paths connected in series between the first load node 102 and the second load node 103 of the electronic circuit 10. The series circuit with the load paths of the first transistor device 1 and the at least one second transistor device 2₁-2ₙ form the load path of the electronic circuit 10.

The electronic circuit 10 shown in FIG. 1 includes n second transistor devices 2₁-2ₙ, with n=4. However, this is only an example. The number of second transistor devices 2₁-2ₙ can be selected depending on the desired application where the electronic circuit 10 is to used. In general, the electronic circuit 10 includes one or more second transistor devices 2₁-2ₙ, that is n≧1.

In FIG. 1, the individual second transistor devices 2₁-2ₙ, nodes of these second transistor devices 2₁-2ₙ, parameters of these second transistor devices 2₁-2ₙ, and electronic devices associated with these second transistor devices 2₁-2ₙ have identical reference characters that are only different by a subscript index, which is either 1, 2, 3, or n in the embodiment shown in FIG. 1. In the following, when an explanation applies to each of the second transistor devices 2₁-2ₙ or when a differentiation between the individual second transistor devices 2₁-2ₙ is not necessary, reference characters without subscript index will be used.

The first transistor device 1 includes a first load node 12 and a second load node 13, wherein the load path of the first transistor device 1 is an electrical path between the first load node 12 and the second load node 13. Equivalently, each of the second transistor devices 2 includes a first load node 22 and a second load node 23, wherein the load path of each second transistor device 2 is an electrical path between the first load node 22 and the second load node 23. Further, the first transistor device 1 includes a drive node 11, and each of the second transistor devices 2 includes a drive node 21.

According to one embodiment, the first transistor device 1 and each of the second transistor devices 2 is a normally-off transistor device. The use of normally-off devices instead of normally-on devices may be beneficial in terms of the overall on-resistance of the electronic circuit. Referring to the explanation below, the overall on-resistance substantially corresponds to the sum of the on-resistance of the individual first and second transistor devices. Usually, a normally-on device can be implemented with a lower on-resistance than a comparable normally-on device having the same voltage blocking capability and chip size as the normally-off device. Thus, an electronic circuit with a desired voltage blocking capability and a desired chip size can be implemented with a lower on-resistance when normally-off devices are used.

In the embodiment shown in FIG. 1, the first transistor device 1 and each of the second transistor devices 2 is an n-type enhancement MOSFET. However, this is only an example. Instead of n-type enhancement MOSFETs, other types of normally-off MOSFETs or IGBTs may be used as well. If the first transistor device 1 and the second transistor devices 2 are implemented as MOSFETs the drive nodes 11, 21 of these transistor devices 1, 2 are gate nodes, the first load nodes are source nodes, and the second load nodes are drain nodes.

In the embodiment shown in FIG. 1, the second transistor devices 2₁-2ₙ have their load paths connected in series such that one of the second transistor devices 2₁-2ₙ, such as the second transistor device 2₁, has the first load node 22₁ connected to the second load node 13 of the first transistor device 1, and each of the other second transistor devices, such as transistor devices 2₂-2ₙ have their first load node 22₂-22ₙ connected to the second load node of a neighboring second transistor device in the series circuit. That is, the second transistor device 2₂ has the first load node 22₂ connected to the second load node 23₁ of the second transistor device 2₁, the second transistor device 2₃ has the first load node 22₃ connected to the second load node 23₂ of the second transistor device 2₂, and so on.

According to one embodiment, the load path of the first transistor device 1 is connected between the first load node 102 of the electronic circuit 10 and the series circuit with the second transistor devices 2₁-2ₙ. In the embodiment shown in FIG. 1, the first load node 12 of the first transistor device 1 is connected to the first load node 102 of the electronic circuit 10 and the series circuit with the second transistor devices 2₁-2ₙ is connected between the second load node 13 of the first transistor device 1 and the second load node 103 of the electronic circuit 10. The second load node of one of the second transistor devices 2, namely the second load node 23ₙ of the second transistor device 2ₙ is connected to the second load node 103 of the electronic circuit 10.

Referring to FIG. 1, the first transistor device 1 has the drive node 11 coupled to the input node 101 of the electronic circuit 10, and each of the second transistor devices 2₁-2ₙ has the respective drive node 21₁-21ₙ coupled to the input node 101 of the electronic circuit 10. In particular, each of the first transistor device 1 and the second transistor devices 2₁-2ₙ have the respective drive node 11, 21₁-21ₙ coupled to the input node 101 of the electronic circuit 10 such that in an on-state of the electronic circuit 10 each of the first transistor device 1 and the second transistor devices 2₁-2ₙ receives a drive voltage based on the input voltage Vin received at the input node 101. Operation of the electronic circuit 10 in the on-state is explained in greater detail herein below. In the embodiment shown in FIG. 1, the drive node 11 of the first transistor device 1 is directly connected to the input node 101, and the drive node 21 of each of the second transistor devices 2 is connected to the input node 101 through a rectifier element 3. The individual rectifier elements 3 are implemented as diodes, in particular as bipolar diodes in the embodiment shown in FIG. 1. In the specific embodiment shown in FIG. 1, an anode node (anode terminal) of each diode 3 is connected to the input node 101, and a cathode node (cathode terminal) of each diode 3 is connected to drive node of the corresponding second transistor device 2.

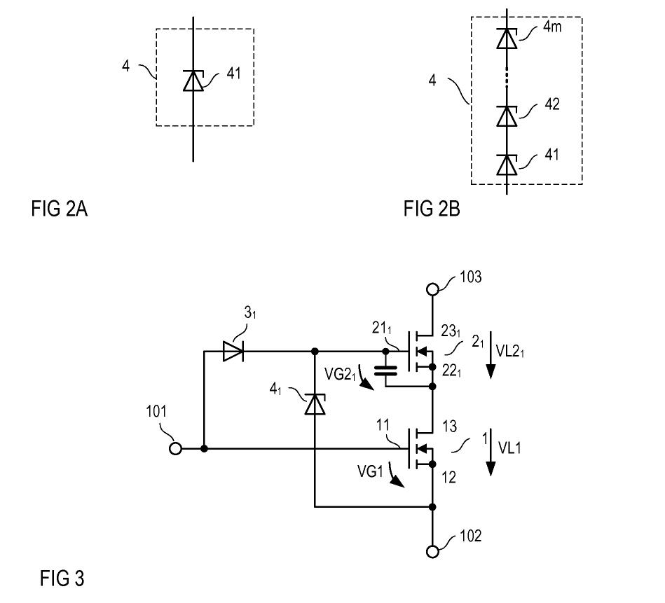

Further, the drive node 21 of each of the second transistor devices 2 is coupled to the load path of the electronic circuit 10. In particular, the drive node 21 of each second transistor device 2 is coupled to the load path of the electronic circuit 10 such that in an off-state of the electronic circuit 10 a drive voltage VG2 of each second transistor device 2 is governed by a load path voltage VL1, VL2 of at least one other transistor device. Operation of the electronic circuit in the off-state is explained in greater detail herein below. The “at least one other transistor device” is either the first transistor device 1 or a second transistor device 2 other than the second transistor device 2 that receives the drive voltage. According to one embodiment, the drive node 21 of each second transistor device 2 is connected to the load path via a voltage limiting element 4. Each of these voltage limiting elements 4 may include one Zener diode 41, as shown in FIG. 2A, or may include a plurality of Zener diodes 41, 42, 4n connected in series, as shown in FIG. 2B. Although the voltage limiting elements 4 are drawn as single Zener diodes in FIG. 1, each of these voltage limiting elements 4 may include two or more Zener diodes connected in series. The number of Zener diodes connected in series in one voltage limiting element 4 defines the breakthrough voltage of the voltage limiting element 4. This is explained in greater detail herein below.

In the embodiment shown in FIG. 1, the voltage limiting elements 4 are connected such that the electrical potential at the drive node 21 of each second transistor device 2 may rise above the electrical potential at the circuit node of the load path to which the drive node is coupled to. In the following, a voltage limiting element 4 connected to the drive node 21 of a second transistor device 2 will be referred to as voltage limiting element associated with the second transistor device 2. Each voltage limiting element 4 associated with a second transistor device 2 is connected to a circuit node of the load path that is distant to the load nodes of the second transistor device 2 it is associated thereto. For example, the voltage limiting element 4₁ associated with the second transistor device 2₁ is connected to the first load node 12 of the first transistor device 1 so that the load path of the first transistor device 1 is located between the circuit node to which the voltage limiting element 4₁ is connected to and the first load node 22₁ of the second transistor device 2₁. In the embodiment shown in FIG. 1, in each case, there is the load path of one transistor device between the circuit node to which one voltage limiting element is connected to and the first load node 22 of the second transistor device the voltage limiting element 4 is associated to. Thus, in the off-state of the electronic circuit 10, the drive voltage of each second transistor device 2 is governed by a load path voltage of either the first transistor device 1 or a second transistor device 2 and by the breakthrough voltage of the associated voltage limiting element. This is explained in greater detail herein below.

According to one embodiment (illustrated in dotted lines in FIG. 1), the first transistor 1 and each of the second transistors 2₁-2ₙ has an individual drive resistor (gate resistor) 7₀, 7₁-7ₙ connected between the respective control node 21₀, 21₁-21 ₙ and the input node 101. The individual drive resistor (gate resistor) 7₀, 7₁⁻7ₙ may be implemented to have substantially the same resistance, or may be implemented with different resistances.

According to another embodiment (illustrated in dashed lines in FIG. 1) the first transistor device 1 and the second transistor devices 2₁-2ₙ have one common drive resistor (gate resistor) in common. This resistor 7 is connected between the input node 101 and the individual rectifier elements 3₁-3ₙ.

According to yet another embodiment (illustrated in dashed and dotted lines) two or more of the second transistors 2₁-2ₙ share one drive resistor (gate resistor) 7₁. In this embodiment, the drive resistor is connected between the input 101 sided nodes of two rectifier elements. In the embodiment shown in FIG. 1, the drive resistor 7₁ is connected between rectifier elements 3₁ and 3₂ so that the second transistor devices 2₂-2ₙ share the drive resistor 7₁ while operation of the other transistor devices (1 and 2₁) is not affected by this drive resistor 7₁.

The electronic device 10 is in the on-state when the first transistor device 1 and each of the second transistor devices 2₁-2ₙ is in an on-state. The MOSFETs shown in FIG. 1 are voltage-controlled devices (switches) that are in the on-state, when the respective drive voltage VG1, VG2₁-VG2ₙ is above a respective threshold voltage. In the MOSFETs shown in FIG. 1, the drive voltage is the voltage between a drive node (gate node) 11, 21₁-21 ₙ and the first load node (source node) 12, 22₁-22ₙ. A MOSFET has an internal gate-source capacitance between the gate node and the source node. In FIG. 1, the gate-source capacitance of each second transistor device (MOSFTEs) 2 is illustrated as a capacitor connected between the drive node (gate node) 21 and the first load node (source node). The drive voltage VG2 is the voltage across these gate-source capacitances. The first transistor device 1 also includes an internal gate-source capacitance. However, this gate-source capacitance is not explicitly illustrated in FIG. 1.

The electronic circuit 1 is in the on-state, when the input voltage Vin has a voltage level that is high enough to switch on the first transistor device 1 and each of the second transistor devices 2₁-2ₙ. In the on-state of the electronic circuit 10, the drive voltage VG1 of the first transistor device 1 corresponds to the input voltage Vin, so that

VG1=Vin (1a).

The drive voltage VG2₁ of the second transistor device 2₁ directly connected to the first transistor device 1 is given as

VG2₁=Vin−VF3₁−VL1 (1b),

where VF3₁ is the forward voltage of the diode 3₁ associated with the second transistor device 2₁, and VL1 is the load path voltage of the first transistor device 1 in the on-state. The drive voltage of each of the other second transistor devices 2₂-2ₙ is given as

VG2ᵢ=Vin−VF3ᵢ−VL1−Σₖ₌₁ⁱ⁻¹VL2ₖ (1c).

In the on-state, the voltage level of the load path voltage VL1, VL2₁-VL2ₙ of the first transistor device 1 and of each of the second transistor devices 2 is dependent on the specific type of transistor device, in particular on the voltage blocking capability of the transistor device. According to one embodiment, the first transistor device 1 and each of the second transistor devices 2 are selected to have a voltage blocking capability of between 10V and 100V. In this case, the voltage level of the load path voltage VL1, VL2 in the on-state is typically between 0.03V and 0.3V. According to one embodiment, the voltage blocking capabilities of the individual second transistor devices 2 are substantially the same. According to another embodiment, the individual second transistor devices 2 have mutually different voltage blocking capabilities.

The forward voltage VF3 of the diodes 3 is, for example, about 0.7V. The threshold voltage of the first transistor device 1 and of each of the second transistor devices 2 is, for example, between 0.5V and 2V. However, the voltage level of the drive voltage (gate-source voltage) at which the respective transistor device reaches a specified low on-resistance (and, therefore, a low voltage level of the load path voltage) is somewhat higher and is, for example, between 5V and 10V. An on-level of the input voltage Vin, which is a voltage level of the input voltage Vin that drives the electronic circuit 10 into the on-state, may easily be calculated based on the parameters explained hereinbefore. This on-level is, in particular, dependent on the number of second transistor devices 2 in the series circuit. According to one embodiment, the on-level of the input voltage Vin is, in particular, selected such that the second transistor device 2ₙ that is connected to the second load node 103 of the electronic circuit 10 receives a drive voltage VG2ₙ that completely switches on this second transistor device 2ₙ. Dependent on the number of second transistor devices 2, the on-level of the input voltage Vin may range between 5V and 20V. Thus, a conventional drive circuit for driving a power transistor, such as a power MOSFET or a power IGBT may be used to drive the electronic circuit 10.

In the series circuit with the first transistor device 1 and the plurality of the second transistor devices 2, each of the second transistor devices 2 has a distance to the first transistor device 1. The distance between one second transistor 2ᵢ and the first transistor 1 can be defined as the number i−1 of second transistors 2 that are located between the second transistor 2ᵢ and the first transistor 1. For example, the distance between the second transistor 2₁ and he first transistor is 0, while the distance between the second transistor 2ₙ and the first transistor 1 is n−1. Considering equation (1c), the drive voltage VG2 of a second transistor 2 is the lower the larger the distance between the second transistor 2 and the first transistor 1 in the series circuit.

According to one embodiment, the second transistors 2 are designed to have substantially the same device parameters (i.e. characteristics) such as, for example, the same on-resistances, the same threshold voltages, the same voltage blocking capability, etc. According to another embodiment, the second transistors 2 are designed to have different device parameters such that the on-resistance of a second transistor 2 is dependent on the distance to the first transistor. In particular, a second transistor 2 more distant to the first transistor 1 may be implemented with a lower on-resistance than a second transistor 2 closer to the first transistor 1. That is, the on-resistance of the individual second transistors 2 decreases as their distance to the first transistor 1 increases. A lower on-resistance of a second transistor that is more distant to the first transistor 1 may help to compensate for a lower drive voltage VG2 of this transistor, as explained with reference to equation (1c). Usually, the on-resistance of a transistor is dependent on the chip-size and the number of parallel transistor cells. Thus, a lower on-resistance may be obtained by increasing the chip-size and the number of transistor cells, respectively.

According to one embodiment, the second transistors 2 and the first transistor 1 are designed to have substantially the same device parameters such as, for example, the same on-resistances, the same threshold voltages, the same voltage blocking capability, etc.

In the on-state of the electronic circuit 10, the individual voltage limiting elements 4 block so that the voltage levels at the respective drive nodes 21 may rise above the voltage levels at the circuit nodes of the load path to which the respective voltage limiting element 4 is connected to. That is, the breakthrough voltage of each voltage limiting element 4 is higher than the on-level of the input voltage Vin.

The electronic circuit 10 switches from the on-state to the off-state when the voltage level of the input voltage Vin changes from the on-level to an off-level. An off-level of the input voltage Vin is a voltage level that switches off the first transistor device 1 which directly receives the input voltage Vin as the drive voltage VG1. The off-level of the input voltage Vin is a voltage level below a threshold voltage level of the first transistor device 1. According to one embodiment, the off-level of the input voltage Vin corresponds to 0V. For the purpose of explanation, it is assumed that the load path of the electronic circuit 10 is connected in series with a load Z and that the series circuit of the load Z and the electronic circuit 10 is connected between supply voltage terminals. In the embodiment shown in FIG. 1, the electronic circuit 10 is connected as a low-side switch. That is, the electronic circuit 10 is connected between a load Z and a terminal with a negative supply potential V1 or reference potential, respectively. However, this is only an example. The way of operation of the electronic circuit 10 is the same when the electronic circuit 10 is connected as a high-side switch, that is, when the electronic circuit 10 is connected between the load Z and the terminal for the positive supply potential V2. In each case, the input voltage Vin is the voltage between the input node 101 and the first load node 102 of the electronic circuit 10.

When the first transistor device 1 switches off, the voltage level of the load path voltage VL1 increases. When the voltage level of the load path voltage VL1 starts to increase, the second transistor device 2₁ directly connected to the first transistor device 1 is still in the on-state as the gate-source capacitance is still charged and the associated diode 3₁ prevents the gate-source capacitance from being discharged when the voltage level of the input voltage Vin changes from the on-level to the off-level. When the voltage level of the load path voltage VL1 of the first transistor device 1 increases such that the load path voltage VL1 plus the drive voltage VG2₁ of the second transistor device 2₁ reach the breakthrough voltage (limiting voltage) of the voltage limiting element 4₁ associated with the second transistor device 2₁ (VL1+VG2₁=VBR4₁, where VBR4₁ is the breakthrough voltage of the voltage limiting element 4₁) the gate-source capacitance of the second transistor device 2₁ starts to be discharged, so that the second transistor device 2₁ starts to switch off. This causes the voltage level of the load path voltage VL2₁ of the second transistor device 2₁ to increase. The voltage level of the load path voltage VL1 of the first transistor device 1 may still increase until the second transistor device 2₁ completely switches off, which is when the drive voltage VG2₁ of the second transistor device 2₁ has decreased to below the threshold voltage of the second transistor device 2₁. At this time, the voltage level VL1 of the first transistor device 1 substantially corresponds to the breakthrough voltage of the voltage limiting element 4₁ (assuming that the threshold voltage of the second transistor device 2₁ is substantially lower than the breakthrough voltage of the voltage limiting element 4₁).

In the same way in which the first transistor device 1 switches off the second transistor device 2₁ when the load path voltage VL1 of the first transistor device 1 increases, the second transistor device 2₁ switches off the second transistor device 2₂, and so on. That is, switching off the first transistor device 1 starts a chain-reaction that subsequently switches off the second transistor devices 2₁, 2₂, and so on. In the off-state of the electronic circuit 10, not necessarily each of the second transistor devices 2₁-2ₙ is switched off. How many of the second transistor devices 2₁-2ₙ are switched off, is dependent on the supply voltage between the supply potentials V1, V2 and the breakthrough voltages on the individual voltage limiting elements 4. If, for example, the supply voltage is lower than the sum of the breakthrough voltages of the voltage limiting elements 4₁-4₃, only the first transistor device 1 and some of the second transistor devices 2₁, 2₂ may switch off.

In the embodiment shown in FIG. 1, the voltage limiting element 4₁ substantially defines the voltage level of the load path voltage VL1 in the off-state, the voltage limiting element 4₂ substantially defines the voltage level of the load path voltage VL2₁ in the off-state, and so on. According to one embodiment, the breakthrough voltage of each voltage limiting element 4 is lower than the voltage blocking capability of the transistor device 1, 2 the load path voltage of which it defines.

In the embodiment shown in FIG. 1, the drive nodes 21 of the individual second transistor devices 2 are coupled to the load path of the electronic circuit 10 such that the load path voltage of only one transistor device governs the drive voltage of each second transistor device 2 in the off-state of the electronic circuit 10. However, this is only an example. According to another embodiment (not shown), the load path voltages of two or more transistor devices govern the drive voltage of one second transistor device. For example, the voltage limiting element 4₂ associated with the second transistor device 2₂ may be connected to the first load node 12 of the first transistor device 1 instead of the first load node 22₁ of the second transistor device 2₁. In this case, the sum of the load path voltages VL1, VL2₁ of the first transistor device 1 and the second transistor device 2₁ would govern the drive voltage VG2₂ of the second transistor device 2₂ in the off-state of the electronic circuit 10.

The overall voltage blocking capability of the electronic circuit 10 is defined by the sum of the voltage blocking capabilities of the first transistor device 1 and the second transistor devices 2₁-2ₙ. Thus, the electronic circuit 10 may easily be adapted to different load scenarios by simply adding one or more second transistor devices 2, the associated rectifier elements 3, and voltage limiting elements 4, or by removing one or more of the second transistor devices 2, the associated rectifier element 3 and voltage limiting elements 4. The overall on-resistance of the electronic circuit 10 is given by the sum of the on-resistances of the transistor devices 1, 2₁-2ₙ in the series circuit.

FIG. 3 shows a modification of the electronic circuit 10 of FIG. 1. In the electronic circuit according to FIG. 3, there is only one second transistor device 2₁.

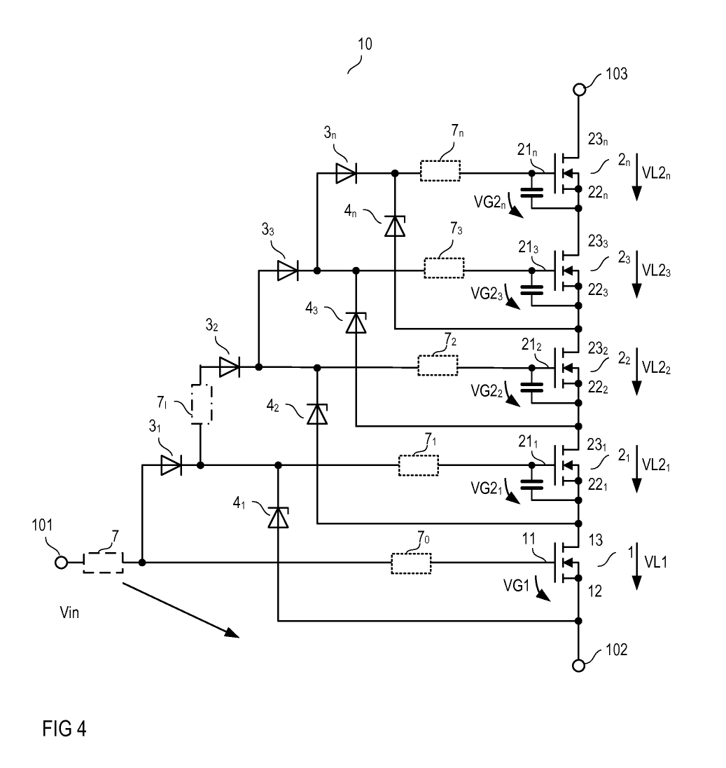

FIG. 4 shows a further modification of the electronic circuit 10 shown in FIG. 1. In this electronic circuit 10, there is a series circuit with rectifier elements 3₁-3ₙ connected between the input node 101 and the drive node 21ₙ of the second transistor devices 2ₙ, which is the second transistor device that is directly connected to the second load node 103. This second transistor device 2ₙ is the second transistor device that is most distant to the first transistor device 1 in the load path of the electronic circuit 10. The number of rectifier elements 3₁-3ₙ in the series circuit corresponds to the number of second transistor devices 2₁-2ₙ. This series circuit with rectifier elements 3₁-3ₙ has taps, with the drive node 21 of each second transistor device 2 being connected to one of these taps. Thus, the second transistor device 2₁ that is closest to the first transistor device 1 is connected to the input node 101 via a first rectifier element 3₁, a neighboring second transistor device 2₂ is connected to the input node 101 via the rectifier element 3₁ and a further rectifier element 3₂, and so on. The drive node 21ₙ of the second transistor device 2ₙ is connected to the input node 101 via the overall series circuit with the rectifier elements 3₁-3ₙ.

The way of operation of the electronic circuit 10 shown in FIG. 4 corresponds to the way of operation of the electronic circuit 10 shown in FIG. 1, with the difference that in the electronic circuit shown in FIG. 4, the drive nodes of the second transistor devices 2₂-2ₙ are connected to the input node 101 via more than one rectifier element. Thus, at a given on-level of the input voltage Vin, the drive voltages of the second transistor devices 2₂-2ₙ are slightly lower than the drive voltages of the corresponding transistor devices 2₂-2ₙ in the electronic circuit 10 shown in FIG. 1. In the electronic circuit 10 shown in FIG. 4, the blocking voltage of each rectifier element 3₁-3ₙ in the off-state of the electronic circuit 10 substantially corresponds to the load path voltage of the associated second transistor device 2₁-2ₙ. In the electronic circuit 10 shown in FIG. 1, the blocking voltage of the individual rectifier elements 3₁-3ₙ increases as the distance of the associated second transistor device 2₁-2ₙ to the first transistor device 1 increases. For example, the rectifier element 3ₙ associated with the second transistor device 2ₙ has a higher blocking voltage in the off-state of the electronic circuit 10 than the rectifier element 3₃ associated with the second transistor device 2₃.

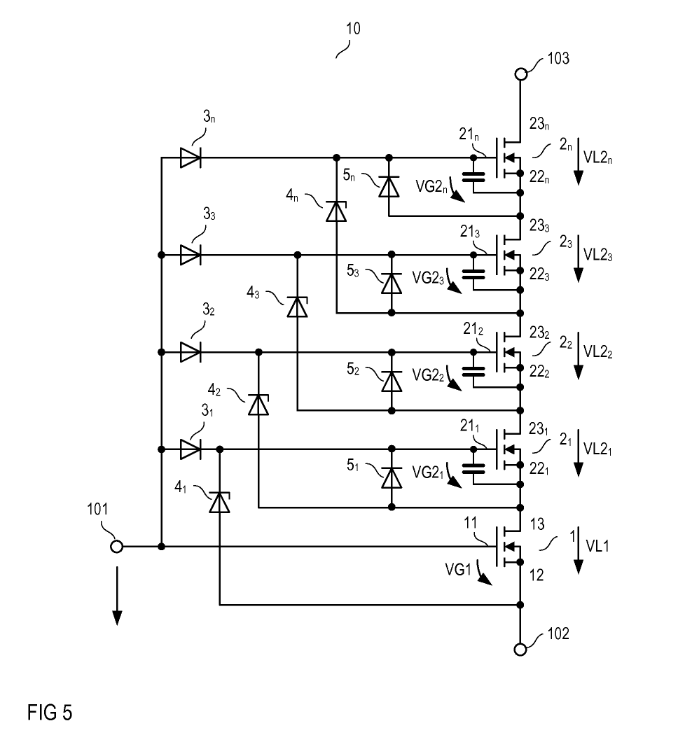

FIG. 5 shows a further modification of the electronic circuit 10 shown in FIG. 1. In the electronic circuit 10 shown in FIG. 5, the drive node (gate node) 21 of each second transistor device is coupled to a corresponding first load node (source node) 22 via a further rectifier element 5. In the present embodiment, where the individual transistor devices are n-type transistor devices, a cathode node of the further rectifier element 5 is connected to the drive node 21, and an anode node of the further rectifier element 5 is connected to the second load node 22. These further rectifier elements 5 help to prevent the electrical potential at the drive node 21 from significantly decreasing below the electrical potential at the second load node 22 when the electronic circuit 10 is in the off-state. Parasitic effects, such as leakage currents of the voltage limiting elements 3₁-3ₙ may cause the gate-source capacitances to be charged or discharged in the off-state. The further rectifier elements 5 counteract those parasitic effects.

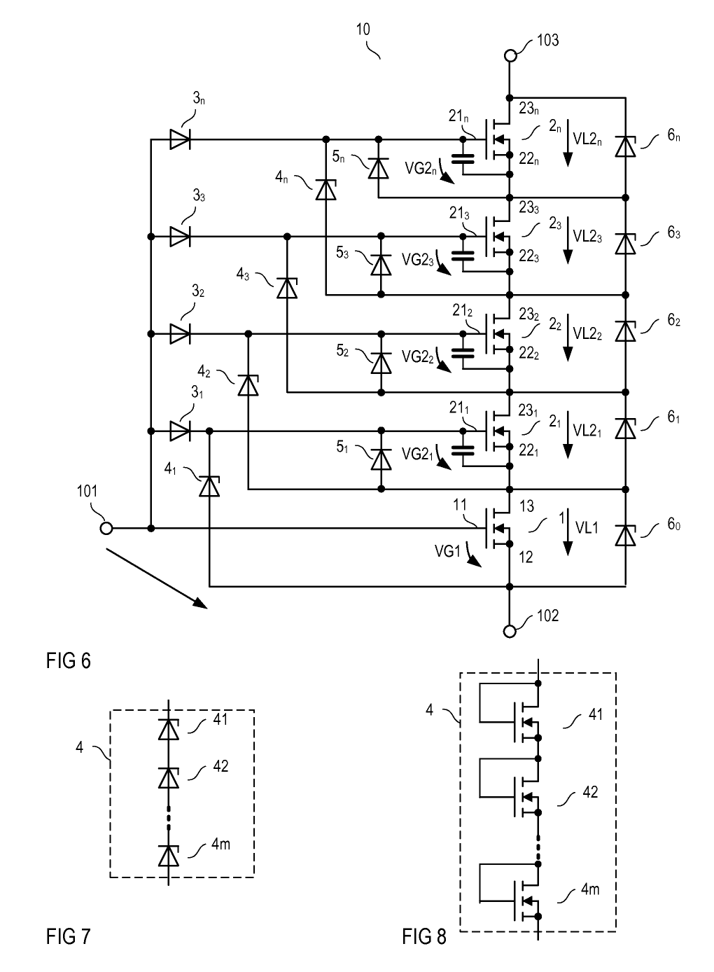

FIG. 6 shows a further modification of the electronic circuit 10 shown in FIG. 6. In the electronic circuit shown in FIG. 6, further voltage limiting elements 6₁-6ₙ are connected in parallel with the load paths of the individual second transistor devices 2. Optionally, a further rectifier element 6₀ is connected in parallel with the load path of the first transistor device 1. These voltage limiting elements 6₁-6ₙ and 6₀, respectively, limit the voltage across the load paths of those second transistors 2₁-2ₙ that have switched off. According to one embodiment, each of the voltage limiting elements 6₁-6ₙ and 6₀, respectively, includes at least one Zener diode or Avalanche diode

The further rectifier elements 5 and the further voltage limiting elements 6 shown in FIGS. 5 and 6 can, of course, also be implemented in a circuit topology as shown in FIG. 5 in which the individual drive nodes 21 of the second transistor devices 2 are connected to taps of a series circuit with the rectifier elements 3₁-3ₙ.

In each of the embodiments explained above, a conventional drive circuit (not shown) can be used to drive the electronic circuit 10 (that is, to operate the electronic circuit 10 as an electronic switch). This drive circuit is configured to either generate an on-level or an off-level of the input voltage Vin.

Although each of the voltage limiting elements 4₁-4ₙ and 6₁-6ₙ is drawn as a Zener diode in the drawings explained above, it should be noted that these voltage limiting elements 4₁-4ₙ and 6₁-6ₙ are not restricted to be implemented with one Zener diode. Dependent on the desired limiting voltage each of the voltage limiting elements may include several Zener diodes or Avalanche diodes connected in series. FIG. 7 shows one embodiment of a voltage limiting element 4 that includes m Zener diodes 41, 42, 4m (with m=3 in this embodiment) connected in series. In this embodiment, the limiting voltage corresponds to the sum of the breakthrough voltages of the individual Zener diodes 41, 42, 4m. The number m is depends upon the desired limiting voltage. Instead of Zener diodes Avalanche diodes may be used as well. The voltage limiting element 4 shown in FIG. 7 represents one of the voltage limiting elements 4₁-4ₙ explained before. However, the voltage limiting elements 6₁-6ₙ may be implemented in the same way.

According to another embodiment, the voltage limiting element 4 (that represents one of the voltage limiting elements 4₁-4ₙ or 6₁-6ₙ explained before) includes at least one transistor device. The at least one transistor device includes a control terminal and two load terminals and has the control terminal connected to one of the load terminals. According to one embodiment shown in FIG. 8, the voltage limiting element includes at least one MOSFET 41, 42, 4m which has its gate terminal connected to its drain terminal. The at least one MOSFET switches on when a load path voltage (drain-source voltage) reaches a threshold voltage of the MOSFET. Thus, the threshold voltage of the at least one MOSFET defines the limiting voltage of the voltage limiting element. If the voltage limiting element 4 includes two or more MOSFETs connected in series, the limiting voltage corresponds to the sum of the threshold voltages of the individual MOSFETs. In the embodiment shown in FIG. 8, m=3 MOSFETs are connected in series. However, this is only an example. The number m is dependent upon the desired limiting voltage.

The voltage limiting element shown in FIG. 8 is not restricted to be implemented with MOSFET, but may be implemented with IGBTs or JFETs (Junction Field-Effect Transistors) as well. Further, the voltage limiting element may be implemented with n-type transistors (as shown) or p-type transistors. However, as p-type transistors have a negative threshold voltage (as opposed to a positive threshold voltage in an) the polarity of a voltage limiting element implemented with p-type transistors has to be inverted as compared to the polarity of a voltage limiting element implemented with n-type transistors. That is, a voltage limiting element implemented with n-type transistors may be connected such that the voltage to be limited is applied between the drain and source node of the at least one transistor, while a voltage limiting element implemented with p-type transistors may be connected such that the voltage to be limited is applied between the source and drain node of the at least one transistor.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second” and the like, are also used to describe various elements, regions, sections, etc. and are also not intended to be limiting. Like terms refer to like elements throughout the description.

As used herein, the terms “having,” “containing,” “including,” “comprising” and the like are open ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An electronic circuit, comprising:
an input node configured to receive an input voltage, and a load path between a first load node and a second load node;
a first transistor device, and n second transistor devices, with n≧1, wherein load paths of the first transistor device and the n second transistor devices are connected in series, thereby forming the load path of the electronic circuit,
wherein each of the first transistor device and the n second transistor devices has a drive node coupled to the input node of the electronic circuit, and
wherein each of the n second transistor devices has the drive node coupled to the load path of the electronic circuit.

2. The electronic circuit of claim 1, wherein each of the first transistor device and the n second transistor devices is a normally-off transistor device.

3. The electronic circuit of claim 2, wherein each of the first transistor device and the n second transistor devices is one of a MOSFET and an IGBT.

4. The electronic circuit of claim 1, wherein each of the n second transistor devices has the drive node coupled to a circuit node of the load path of the electronic circuit that is distant to its own load path.

5. The electronic circuit of claim 1,
wherein each of the first transistor device and the n second transistor devices has the drive node coupled to the input node of the electronic circuit such that, in an on-state of the electronic circuit, each of the first transistor device and the n second transistor device receives a drive voltage based on the input voltage.

6. The electronic circuit of claim 1,
wherein each of the n second transistor devices has the drive node coupled to the input node of the electronic circuit via a rectifier element, and
wherein each of the n second transistor devices has the drive node coupled to the load path of the electronic circuit via a voltage limiting element.

7. The electronic circuit of claim 6,
wherein the rectifier element comprises one of a bipolar diode, and a Zener diode.

8. The electronic circuit of claim 6,
wherein the voltage limiting element comprises at least one Zener diode.

9. The electronic circuit of claim 1, further comprising:
at least one further rectifier element connected in parallel with a load path of at least one of the first transistor device and the n second transistor devices.

10. The electronic circuit of claim 1, wherein n≧2.

11. The electronic circuit of claim 1, wherein a further rectifier element is connected between the control node and a first load node of each of the n second transistor devices.

12. The electronic circuit of claim 11, wherein each of the n second transistor devices comprises one of a MOSFET and an IGBT comprising a gate node as the control node and a source node as the first load node.

13. The electronic circuit of claim 1,
wherein each of the n second transistor devices has at least one device parameter, where n≧2, and
wherein a level of the at least one device parameter of the individual n second transistor devices is substantially identical.

14. The electronic circuit of claim 13, wherein the at least one device parameter is selected from the group consisting of:
on-resistance,
voltage blocking capability, and
threshold voltage.

15. The electronic circuit of claim 13,
wherein the first transistor device has at least one device parameter, and wherein a level of the at least one device parameter of the first transistor device is substantially identical with the level of the at least one device parameters in the n second transistor devices.
